(19) United States
(12) Patent Application Publication
(10) Pub. No.: US 2026/0245599 A1
(43) Pub. Date: Aug. 20, 2026

(54) SEMICONDUCTOR MEMORY DEVICE AND MANUFACTURING METHOD

(71) Applicant: Kioxia Corporation, Tokyo (JP)

(72) Inventors: Tatsushi YAGUCHI, Yokkaichi Mie (JP); Masaki TSUJI, Yokkaichi Mie (JP)

(21) Appl. No.: 19/282,263

(22) Filed: Jul. 28, 2025

(30) Foreign Application Priority Data
Feb. 18, 2025 (JP) 2025-024128

(51) Int. Cl. G11C 5/06; H01L 23/00; H10B 43/10; H10B 43/27; H10B 43/35; H10D 30/01; H10D 30/69; H10D 80/30

(52) U.S. Cl. CPC G11C 5/063; H10B 43/10; H10B 43/27; H10B 43/35; H10D 30/0413; H10D 80/30; H10D 30/693; H10W 90/792

(57) ABSTRACT

According to one embodiment, a semiconductor memory device includes a stacked body in which first conductive layers and first insulating layers are alternately stacked. A pillar including a semiconductor layer extends through the stacked body. A slit that penetrates the stacked body is formed. A first material layer is provided on the sidewalls of the slit. A second conductive layer is provided on one end side of the slit. A second material layer is provided in the first material layer on the one end side of the slit. The side walls of the first and second material layers on the one end side of the slit correspondingly taper outwardly from the center of the slit.

### CROSS-REFERENCE TO RELATED APPLICATION

This application is based upon and claims the benefit of priority from Japanese Patent Application No. 2025-024128, filed Feb. 18, 2025, the entire contents of which are incorporated herein by reference.

### FIELD

Embodiments described herein relate generally to a semiconductor memory device and a manufacturing method thereof.

### BACKGROUND

A semiconductor memory device, such as a NAND flash memory, may have a three-dimensional memory cell array in which a plurality of memory cells are three-dimensionally disposed. In such a memory cell array, a slit for dividing the stacked body of the memory cell array into a plurality of pieces is usually formed. When an aspect ratio of the slit is increased, a seam is more likely to remain in a material in which the slit is embedded or filled with material. When a seam remains in the slit structure, the seam may eventually lead to a crack forming in the memory cell array.

### BRIEF DESCRIPTION OF THE DRAWINGS

FIG. 1 is a cross-sectional view showing a configuration example of a semiconductor memory device according to a first embodiment.

FIG. 2 is a plan view showing a configuration example of a semiconductor memory device according to a first embodiment.

FIG. 3 is a cross-sectional view of a semiconductor memory device according to a first embodiment.

FIG. 4 is a cross-sectional view of one pillar.

FIG. 5 is a cross-sectional view of one pillar.

FIG. 6 to FIG. 16 depict aspects of a manufacturing method of a semiconductor memory device according to a first embodiment.

FIG. 17 to FIG. 19 depict aspects of a manufacturing method of a semiconductor memory device according to a second embodiment.

FIG. 20 to FIG. 23 depict aspects of a manufacturing method of a semiconductor memory device according to a third embodiment.

### DETAILED DESCRIPTION

Embodiments provide a semiconductor memory device capable of avoiding or limiting cracks in a memory cell array and a manufacturing method thereof.

In general, according to one embodiment, a semiconductor memory device includes a first stacked body in which first conductive layers and first insulating layers are alternately stacked in a first direction. A second conductive layer is on a first side of the first stacked body in the first direction. A pillar extends in the first direction in the first stacked body. The pillar includes a semiconductor layer. A slit is provided in the first stacked body extending in the first direction and in a second direction intersecting the first direction. The slit has a width dimension in a third direction intersecting the first and second directions. A first material layer is on sidewalls of the slit on a first end side of the slit in the first direction. A second material layer is in the slit between the first material layer on the sidewalls in the third direction. The second material layer has sidewalls on the first end side of the slit which taper outwardly from a center of the slit. The first material layer has sidewalls on the first end side of the slit which correspondingly taper outwardly from the center of the slit along with the sidewalls of the second material layer.

Hereinafter, certain example embodiments of the present disclosure will be described with reference to the drawings. These example embodiments do not limit the present disclosure. The drawings are schematic or conceptual. In the specification and drawings, the same elements are denoted by the same reference symbols.

### First Embodiment

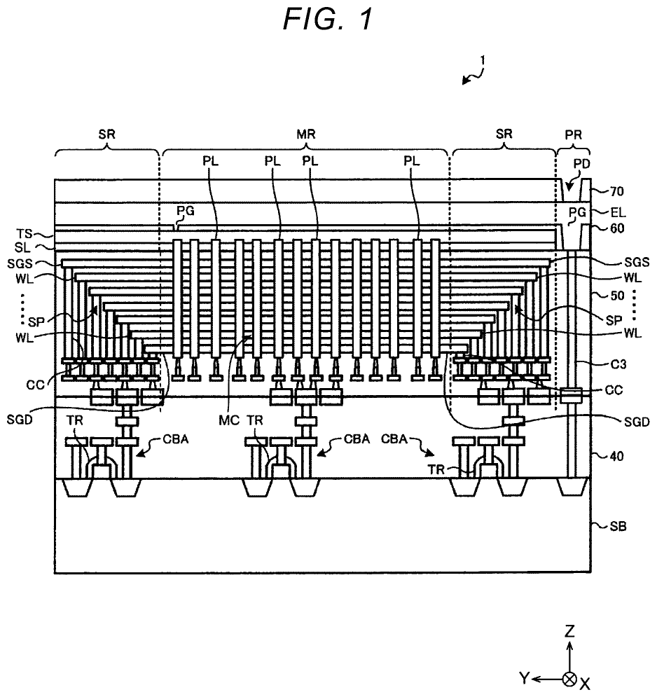

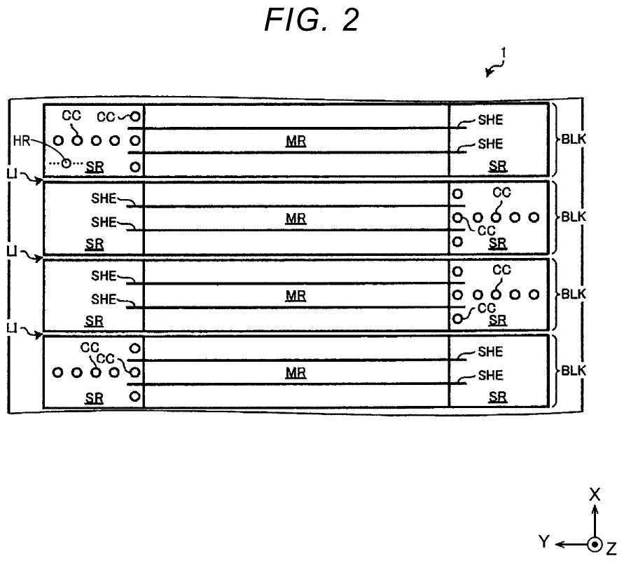

FIG. 1 is a cross-sectional view showing a configuration example of a semiconductor memory device according to the first embodiment. FIG. 2 is a plan view showing a configuration example of the semiconductor memory device according to the first embodiment. In the drawings, configurations that are not necessarily present on the same plane may still be shown for purposes of description. In addition, in the drawings, certain aspects, such as an upper layer wiring or the like may be omitted from the depiction to focus explanation on other aspects.

In the present description, the Z direction is a stacking direction of the word lines WL. The X direction and the Y direction are directions in a plane of a word line WL, and are directions that intersect (for example, are orthogonal to) the Z direction. The X direction and the Y direction intersect each other (for example, are orthogonal to each other). In explanation of drawings, page directions may be referred to as an upward direction or a downward direction. These are up-down page relative directions and are not necessarily fixed or the same drawing to drawing for the depicted components. Nor does such description necessarily imply any device or component orientation with respect to a gravity direction or the like.

A semiconductor memory device 1 includes a semiconductor substrate SB, a peripheral circuit CBA, one or more select gate lines SGD, a plurality of word lines WL, one or more select gate lines SGS, a source layer SL, and an electrode film EL in this order along the Z direction.

The semiconductor substrate SB is, for example, a silicon substrate or the like. The peripheral circuit CBA including the transistor TR, the wiring, or the like is disposed on the surface of the semiconductor substrate SB, and the entire surface is covered with an insulating layer 40. The plurality of word lines WL and the select gate lines SGD and SGS, the entire group of which is covered with the insulating layer 50, are disposed above the semiconductor substrate SB.

As shown in FIGS. 1 and 2, a memory region MR is disposed in a region at the center (middle) of the plurality of word lines WL or the like in the Y direction. A staircase region SR is disposed at both ends of the plurality of word lines WL in the Y direction. The memory region MR and the staircase region SR are sub-divided into a plurality of regions by a plurality of plate-shaped bodies LI that penetrate the plurality of word lines WL in the Z direction and extend lengthwise in the Y direction.

Each region disposed between plate-shaped bodies LI adjacent to each other in the X direction and including a memory region MR and a staircase region SR (or portions thereof) is referred to as a block region BLK. The memory region MR includes a plurality of memory cells that store data in a non-volatile manner, and the block region BLK is a data erasing unit.

The plate-shaped body LI is provided in a slit that penetrates through the stacked body of word lines WL in the Z direction and extends lengthwise in the Y direction. The plate-shaped body LI may be an insulating material embedded in the slit to electrically separate block regions BLK from each other. Alternatively, the plate-shaped body LI may be an insulating layer that covers the inner wall of the slit with a conductive material embedded in the insulating layer. In this case, the conductive material may function as a contact but need not be used electrically at all.

In addition, a plurality of separation layers SHE, which penetrate the select gate line SGD in the Z direction and extend lengthwise in the Y direction, are disposed between the plate-shaped bodies LI adjacent to each other in the X direction. Multiple separation layers SHE may be spaced in the X direction between adjacent plate-shaped bodies LI. The separation layers SHE extend entirely across the memory region MR and reach into the staircase regions SR at both end portions. The separation layers SHE penetrate the select gate SGD in the Z direction, but do not reach the word lines WL.

A plurality of pillars PL are disposed in the memory region MR. The pillars PL extend through the plurality of word lines WL as well as the select gate lines SGD and SGS, and the source layer SL disposed above the word lines WL. A metal layer TS is provided on the source layer SL, and serves to reduce the electrical resistance of the source layer SL.

The electrode film EL is disposed above the metal layer TS with an insulating layer 60 interposed therebetween. The electrode film EL is covered with an insulating layer 70 except for a pad region PD provided in a peripheral region PR located outside the region of the word lines WL in the Y direction or the like. The insulating layer 70 is, for example, a silicon oxide layer, a silicon nitride layer, and a polyimide layer stacked one upon the other from the lower layer side.

The electrode film EL is connected to the source layer SL, a through contact C3, or the like by a plug PG penetrating the insulating layer 60. The through contact C3 is provided in the peripheral region PR and penetrates the insulating layer 50 that covers the word lines WL and the insulating layer 40 that covers the peripheral circuit CBA to be connected to the semiconductor substrate SB.

The semiconductor substrate SB can be controlled from the outside of the semiconductor memory device 1 to be a predetermined potential via the pad region PD and the through contact C3. Further, a power supply and a signal from the outside are supplied to the semiconductor memory device 1 from the pad region PD.

A plurality of memory cells MC are formed at the intersections between a pillar PL and the word lines WL. As a result, the semiconductor memory device 1 is configured as a three-dimensional nonvolatile memory in which the memory cells MC are disposed in three dimensions in the memory region MR.

In the staircase region SR, a step portion SP in which the plurality of word lines WL and the select gate lines SGD and SGS are processed in a stepped shape and terminated is disposed. The separation layers SHE extend from the memory region MR to the portion of the staircase region SR in which the select gate line SGD is processed into a stepped shape. As a result, within the each block region BLK, the select gate line SGD is separated into a plurality of regions. In other words, the separation layers SHE partition (sub-divide) these portions into patterns of a plurality of select gate lines SGD by penetrating the select gate line SGD. A memory region partitioned by the separation layers SHE is called a finger and is a unit of a read or write operation.

A plurality of contacts CC are disposed in the terrace portion of each stage configured with the plurality of word lines WL and the select gate lines SGD and SGS. The plurality of contacts CC extend in the Z direction in the insulating layer 50 and are connected to the word lines WL and the select gate lines SGD and SGS in each layer, respectively.

For each word line WL and select gate line SGS, the one contact CC is connected for each layer. For the select gate lines SGD, at least one contact CC is connected to each partition formed by the separation layers SHE. That is, at least one contact CC is provided for each finger.

In addition to the contact CC, a plurality of support columns HR can be provided around the contacts CC in the staircase region SR. The support column HR can be an insulating material penetrating the stacked body LM. FIG. 2 shows the one support column HR, but a plurality of support columns HR are disposed substantially uniformly in the staircase region SR. The support column HR functions as a support column when the stacked body of the word lines WL is being formed.

In this example, in each of the block regions BLK, the contacts CC are disposed on one side or the other of the staircase regions SR in the Y direction rather than both. As such, with the plurality of block regions BLK disposed spaced from each other in the X direction, the contacts CC are disposed on opposite Y direction ends for each of adjacent block regions BLK in the X direction.

The word lines WL, which are stacked in multiple layers, are individually drawn out by a different contact CC. The contact CC applies a write voltage, a read voltage, and the like to the memory cells corresponding to the word line WL via the word line WL connected to the contact CC.

The semiconductor memory device 1 can be formed by bonding (joining) the insulating layer 40 covering the peripheral circuit CBA to the insulating layer 50 covering the word lines WL. When the electrode pads respectively disposed on the surfaces of the insulating layers 40 and 50 are connected to each other by bonding, the peripheral circuit CBA is electrically connected to the word lines WL, the select gate lines SGS and SGD, and the pillars PL via the contacts CC and the like. As a result, the peripheral circuit CBA can control each memory cell.

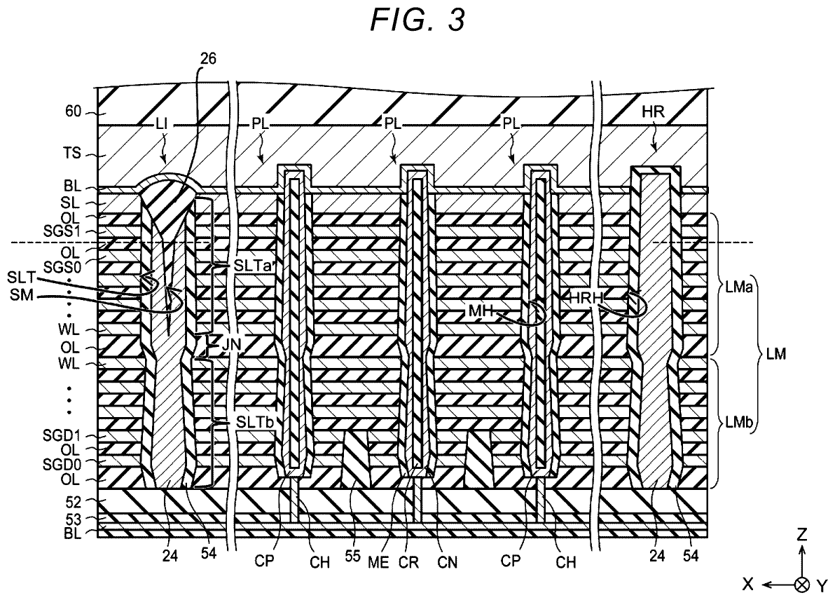

FIG. 3 is a cross-sectional view of the semiconductor memory device according to the first embodiment. FIG. 3 shows a cross section orthogonal to the Y direction. FIG. 3 shows a plate-shaped body LI, pillars PL, and a support column HR arranged side by side.

The metal layer TS, a barrier metal layer BM, and the source layer SL are disposed in this order below the insulating layer 60 (−Z direction).

For the insulating layer 60, an insulating material such as a silicon oxide can be used. For the metal layer TS, a conductive material such as tungsten can be used. The metal layer TS functions as a source electrode of the memory cells together with the source layer SL. For the barrier metal layer BM, titanium, titanium nitride, tantalum, or tantalum nitride can be used. The barrier metal layer BM serves to reduce the diffusion from the metal layer TS.

For the source layer SL, a conductive material such as doped polysilicon can be used. The source layer SL functions as a source electrode of the memory cells and also functions as an etching stopper when the pillars PL are being formed in a manufacturing process of the semiconductor memory device 1.

The stacked body LM, in which word lines WL and insulating layers OL are alternately stacked is provided below the source layer SL (−Z direction). Here, the stacked body LM includes a stacked body LMa provided below the source layer SL and a stacked body LMb provided below the stacked body LMa.

The stacked body LMa has select gate lines SGS1 and SGS0 between a word line WL and the source layer SL in the uppermost layer on the +Z side. The select gate lines SGS1 and SGS0 are select gate lines on the source side.

The stacked body LMb has select gate lines SGD1 and SGD0 below a word line WL in the lowermost layer on the −Z side. The select gate lines SGD1 and SGD0 are select gate lines on the drain side.

The stacked body LMa has word lines WL and insulating layers OL alternately stacked in the Z direction. The stacked body LMb is a stacked body provided in the −Z direction from the stacked body LMa and also has word lines WL and insulating layers OL alternately stacked.

As will be further described below, a memory hole, a slit SLT, and a hole HRH for the support column HR in the stacked body LMa, and a memory hole, a slit SLT, and a hole HRH for the support columns HR in the stacked body LMb are formed separately from each other. Therefore, the pillars PL, the plate-shaped body LI, and the support column HR have in this example a constriction (narrow portion) at position near the interface of the stacked bodies LMa and LMb.

The number of layers used for the word lines WL and the select gate lines SGS and SGD is not limited and may be selected by a device designer or the like. For the word lines WL and the select gate lines SGS and SGD, a conductive material such as tungsten or molybdenum can be used. For the insulating layers OL an insulating material such as silicon oxide can be used.

Insulating layers 52 and 53 are provided below the stacked body LM. The insulating layers 52 and 53 form a portion of the insulating layer 50 (see FIG. 1).

The plate-shaped body LI is provided in a slit SLT that penetrates the stacked body LM in the stacking direction (Z direction) and extends in the Y direction. Therefore, the plate-shaped body LI also penetrates the stacked body LM in the Z direction and extends in the Y direction. One end of the plate-shaped body LI on the side of the source layer SL (+Z direction) penetrates the source layer SL and protrudes into the metal layer TS. This end of the plate-shaped body LI on the side of the source layer SL is covered with the barrier metal layer BM.

This (+Z side) end of the plate-shaped body LI is shown protruding through the source layer SL and into the metal layer TS. However, in other examples, this end of the plate-shaped body need not penetrate through the source layer SL and into the metal layer TS, but rather may be recessed from that depicted. In some examples, this (+Z side) end of the plate-shaped body LI may be flush with the source layer SL.

The plate-shaped body LI includes therein a material layer 24 (inner layer), a material layer 54 (sidewall layer), and a material layer 26 (seam filler). The material layer 54 is provided on the side wall in the slit SLT and is thus between the material layer 24 and the word lines WL and between the material layer 24 and the insulating layers OL. The material layer 54 is an insulating layer/material. As the material layer 54, for example, an insulating material such as silicon oxide is used. The material layer 24 is provided inside the material layer 54 within the slit SLT. The material layer 24 is embedded (filled) inside of the material layer 54. The material layer 24 can be an insulating layer/material or a conductive layer/material. As the material layer 24, for example, an insulating material such as silicon oxide is used or a conductive material such as amorphous silicon, tungsten, or silicon germanium is used. As long as the material layer 54 sufficiently electrically separates the material layer 24 from the word lines WL and the like, the material layer 24 may be a conductive layer/material.

The material layers 24 and 54 fill the slit SLT at the end on the side opposite to the source layer SL and the metal layer TS. However, at the end of the slit SLT on the side of the source layer SL and the metal layer TS, the material layers 24 and 54 do not necessarily completely fill the slit SLT, and a seam SM remains. The seam SM is more likely to remain when the aspect ratio of the slit SLT is increased. Further, as shown in FIG. 3, when the slit SLT is divided into an upper portion and a lower portion, that is, is separately formed as slit portions SLTb and SLTa, a constriction will generally be formed at the connection portion JN (junction region) between the slit portions SLTb and SLTa. The slit portions SLTa and SLTb are formed in the corresponding to the stacked bodies LMa and LMb, respectively. In this case, at the connection portion JN, a deposition gas or the like is likely stay in the slit portion SLTb by being restricted due to the constriction from the other end of the slit SLT, and has difficulty being introduced into the slit portion SLTa. Therefore, the seam SM is likely to be formed in the material layer 24 in the slit portion SLTa.

In the cross section shown in FIG. 3, the total cross-sectional width of the material layers 24 and 54 in the X direction is constricted at the connection portion JN between the stacked body LMa and the stacked body LMb. In other words, the combined width of the material layers 24 and 54 in the X direction narrows in the stacked body LMa and the stacked body LMb as the connection portion JN approaches from either direction. However, the total cross-sectional width of the material layers 24 and 54 in the X direction begins to widened once again after the connection portion JN.

Eventually, as the source layer SL approaches, the width of the material layers 24 and 54 in the X direction narrows again in the stacked body LMa. At the upper end (+Z direction) of the slit SLT, the upper ends of the material layers 24 and 54 taper inwardly in the same direction with respect to the centerline of the slit SLT.

Since the slit portions SLTa and SLTb are formed separately, each has a bowing shape such that the width in the X direction increases to a maximum within each at a position along the depth direction (Z direction) between the upper and lower ends.

The material layer 26 is filled into the material layer 24 from one end (+Z end) of the slit SLT on the side of the source layer SL (+Z side). The material layer 26 is provided within the seam SM that forms in the material layer 24. In the cross section shown in FIG. 3, the width (X direction) of the material layer 26 increases as the source layer SL and the metal layer TS approach. That is, at a height position along the Z direction at which the material layer 26 is present, the material layers 24 and 54 on the side wall of the slit SLT and the side wall of the material layer 26 correspondingly taper inwardly toward the centerline of the slit SLT. That is, material layer 26 gets wider in the X dimension going towards the source layer SL (+Z direction) while the material layers 24 and 54 on each sidewall get correspondingly narrower in the X dimension going towards the source layer SL (+Z direction). This is because, while the portion of the slit SLT with the material layers 24 and 54 is formed in the stacked body LM from the −Z side (side opposite to the source layer SL), the material layer 26 is formed in the stacked body LM from the +Z side (side of the source layer SL). That is, the material layers 24 and 54 and the material layer 26 are formed from the Z direction sides of the slit SLT opposite to each other. For the material layer 26, an insulating material such as a silicon oxide film or a silicon nitride film can be used.

By providing the material layer 26 in the seam SM, the stacked body LM can be prevented from cracking along the slit SLT.

The slit SLT and the plate-shaped body LI penetrate the stacked body LM in the Z direction and extend in the Y direction as shown in FIG. 2. Therefore, for example, when the seam SM is left as it is in the material layers 24 and 54, the plate-shaped body LI is likely to be cracked at the boundary of the slit SLT.

However, according to the present embodiment, the material layer 26 is provided to fill the seam SM. As a result, the cracking in the stacked body LM can be reduced. The material layer 26 may entirely fill the seam SM. However, even if a space/void is left in the seam SM to some extent, the material layer 26 may still cover/close the end of slit SLT on the side of the source layer SL, so that a reduction in cracks can be obtained.

One or more separation layers SHE are provided in the stacked body LM between the plate-shaped bodies LI adjacent to each other in the X direction. Each separation layer SHE penetrates the select gate lines SGD0 and SGD1. As a result, the select gate lines SGD0 and SGD1 are divided into a plurality of partitions (fingers).

The pillars PL extend in the stacking direction (Z direction) of the stacked body LM between the plate-shaped bodies LI adjacent to each other in the X direction. Each pillar PL penetrates the stacked body LM and reaches the source layer SL and the metal layer TS.

The pillars PL are disposed, for example, in a staggered shape when viewed from the Z direction. Each of the pillars PL has, for example, a shape such as a substantially circular shape, a substantially elliptical shape, or an oval shape when viewed from the Z direction.

In the cross section shown in FIG. 3, the pillar PL has a taper (narrowing) in a portion provided in the stacked body LMa and a portion provided in the stacked body LMb, similar to shape of the slit SLT or the support column HR.

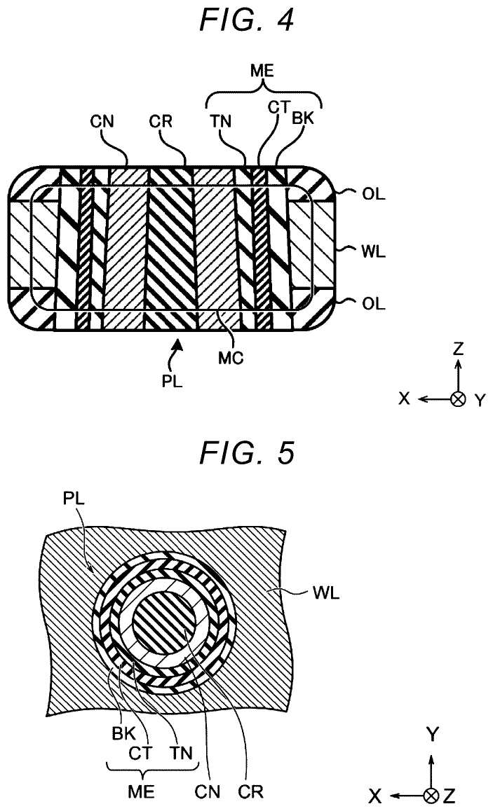

FIGS. 4 and 5 are cross-sectional views showing a configuration example of one pillar. FIG. 4 shows a cross section orthogonal to the Y direction as in FIG. 3. FIG. 5 shows a cross section orthogonal to the Z direction.

As shown in FIGS. 4 and 5, the pillar PL includes a core layer CR, a channel layer CN covering a side wall of the core layer CR, and a memory layer ME covering a side wall of the channel layer CN. As shown in FIG. 3, the pillar PL further includes a cap layer CP disposed at an end portion of the pillar PL.

As shown in FIG. 3, the memory layer ME penetrates the stacked body LM and the source layer SL and reaches the barrier metal layer BM. In addition, the core layer CR and the channel layer CN penetrate the stacked body LM and the source layer SL, and the tip portion thereof on the +Z side further protrudes into the metal layer TS. The end portion of the channel layer CN in the metal layer TS is covered with the barrier metal layer BM. That is, the portion of the channel layer CN that protrudes into the metal layer TS is not covered by the memory layer ME, and the channel layer CN is directly in contact with the barrier metal layer BM. As a result, the channel layer CN is electrically connected to the source layer SL through the barrier metal layer BM.

The cap layer CP at the end portion of the pillar PL on the −Z side makes connection between the channel layer CN and the plug CH. The plug CH electrically connects a bit line BL disposed in the insulating layer 53 to the pillar PL in the stacked body LM. The bit line BL extends lengthwise in the X direction in this example.

As shown in FIGS. 4 and 5, the memory layer ME has a stacked structure including a block insulating layer BK, a charge storage layer CT, and a tunnel insulating layer TN in order from the outer peripheral side of the pillar PL. The charge storage layer CT is, for example, a silicon nitride or the like. The block insulating layer BK, the tunnel insulating layer TN and the core layer CR are, for example, silicon oxide or the like. The channel layer CN and the cap layer CP are, for example, a polycrystalline semiconductor layer or the like such as a polysilicon material.

A portion of the channel layer CN that protrudes at least into the metal layer TS may contain the same type of N-type impurity as doped into the source layer SL. For example, the N-type impurity is arsenic or phosphorus.

As shown in FIG. 4, the memory cells MC are formed in the portions facing the individual word lines WL on the side surface of the pillar PL, respectively. By applying a voltage from the word line WL, data can be written to and read from a memory cell MC.

The select gates STD are formed on portions of the side surfaces of the pillar PL facing the select gate lines SGD0 and SGD1, respectively. In addition, the select gates STS are formed in portions of the side surfaces of the pillar PL facing the select gate lines SGS0 and SGS1, respectively.

By applying a voltage from each of the select gate lines SGD and SGS, the select gates STD and STS can be turned on or off, and the memory cells MC of the pillar PL, to which the select gates STD and STS belong, can be set to a selected state or an unselected state for a data reading or writing.

The plurality of support columns HR are provided around the contacts CC in the staircase region SR. The support column HR functions as a support column to prevent the stacked body LM from being bent under its own weight when a sacrificial layer of the stacked body LM is being replaced with the conductive material of the word lines WL in a replacement step. The support column HR does not have an electrical function, and thus may be formed with the same material layers 24 and 54 as the slit SLT. Of course, in other examples, the support columns HR may be embedded with an insulating material different from the slits SLT. Since the support column HR is a columnar body formed in the hole HRH, although a seam remains, the seam is generally unlikely to cause a crack. Therefore, the support column HR may be formed at the same time and in the same step as the plate-shaped body LI.

The support column HR extends in the stacking direction (Z direction) of the stacked body LM. The support column HR penetrates the stacked body LM and reaches the source layer SL and the metal layer TS.

It is preferable that the plurality of support columns HR are uniformly disposed in the staircase region SR when viewed from the Z direction. As a result, in the replacement step, the stacked body LM can be prevented from being locally bent. Each of the support columns HR has, for example, a shape such as a substantially circular shape, a substantially elliptical shape, or an oval shape when viewed in the Z direction. The size of the support column HR is typically larger than the size of the pillar PL when viewed from the Z direction.

In the cross section shown in FIG. 3, the support column HR has a side wall taper in a portion provided in the stacked body LMa and a portion provided in the stacked body LMb, in the same manner as the slit SLT and the pillar PL.

The material layer 26 is provided in the seam SM of the material layer 24 from the side of the source layer SL. By providing the material layer 26 in the seam SM, the stacked body LM can be prevented from cracking along the slit SLT.

Next, a manufacturing method of the semiconductor memory device 1 according to the first embodiment will be described.

FIGS. 6 to 16 are cross-sectional views showing aspects of the manufacturing method of the semiconductor memory device according to the first embodiment. In FIGS. 6 to 11, the −Z direction is an upward direction. In FIGS. 12 to 16, the +Z direction is an upward direction.

An insulating material 51 and a conductive material SL1 are stacked in this order on a substrate WF. For the insulating material 51, for example, an insulating material such as a silicon oxide film is used. For the conductive material SL1, for example, a semiconductor material such as doped polysilicon is used.

Next, the conductive material SL1 is processed using lithography technology and etching technology, and the conductive material SL1 is selectively removed from a formation region Rslt for the slit SLT. As a result, a groove is formed in the formation region Rslt for the slit SLT.

Next, the insulating material 55 is deposited on the insulating material 51 in the formation region Rslt. At this time, the insulating material 55 is embedded in the groove of the formation region Rslt. For the insulating material 55, for example, the same insulating material as the insulating material 51, such as a silicon oxide film, is used. Next, the insulating material 55 is flattened by using a CMP method or the like.

Next, a material of a conductive layer SL2 is deposited on the insulating material 55. For the material of the conductive layer SL2, for example, a semiconductor material such as doped polysilicon is used. As a result, the structure shown in FIG. 6 is obtained. The conductive layer SL2 ultimately functions as a source layer SL. In the formation region Rslt, the insulating material 55 is connected to the insulating material 51.

Next, as shown in FIG. 7, the stacked body LMsa (a first stacked body) is formed by alternately stacking a plurality of sacrificial layers NL and a plurality of insulating layers OL on the conductive layer SL2. For the sacrificial layer NL, for example, an insulating material such as a silicon nitride film is used. The sacrificial layer NL is replaced with a conductive material in a later replacement step and is thus in the ultimate positions of the word lines WL and the select gate lines SGS.

Next, although not specifically depicted, the sacrificial layer NL and the insulating layer OL are processed into stepped shapes in the staircase region SR of the stacked body LMsa. Such processing is possible by repeating slimming of a mask pattern and etching of the stacked body LMsa. Next, the staircase region SR thus formed is covered with the insulating layer 50.

Next, a plurality of memory holes MHa extending in the Z direction are formed in the stacked body LMsa. At this time, the conductive material SL1 below the stacked body LMsa functions as an etching stopper (etch stop). Therefore, the memory holes MHa penetrate the stacked body LMsa and reach the conductive material SL1.

The slit portion SLTa and a hole HRHa can be formed in the stacked body LMsa at the same time as the formation of the memory holes MHa or in a different step from the memory holes MHa.

At this time, one end of the slit portion SLTa reaches the insulating material 55 and terminates inside the insulating material 55.

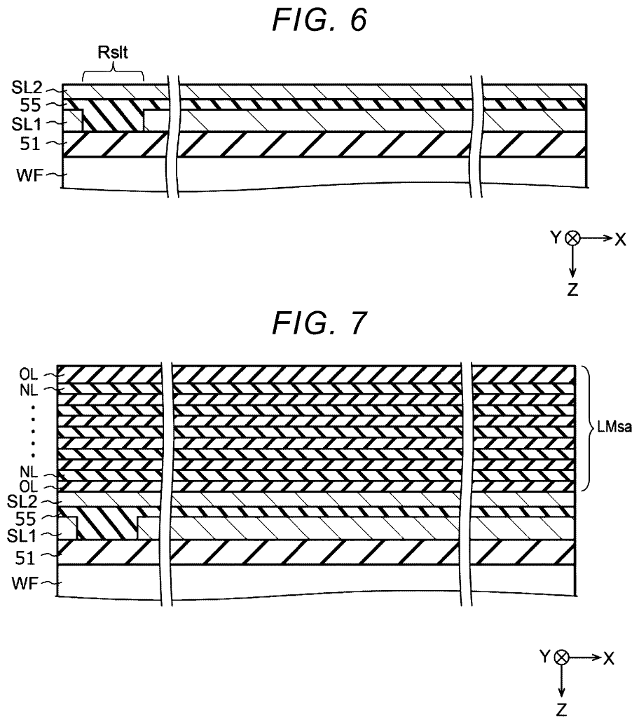

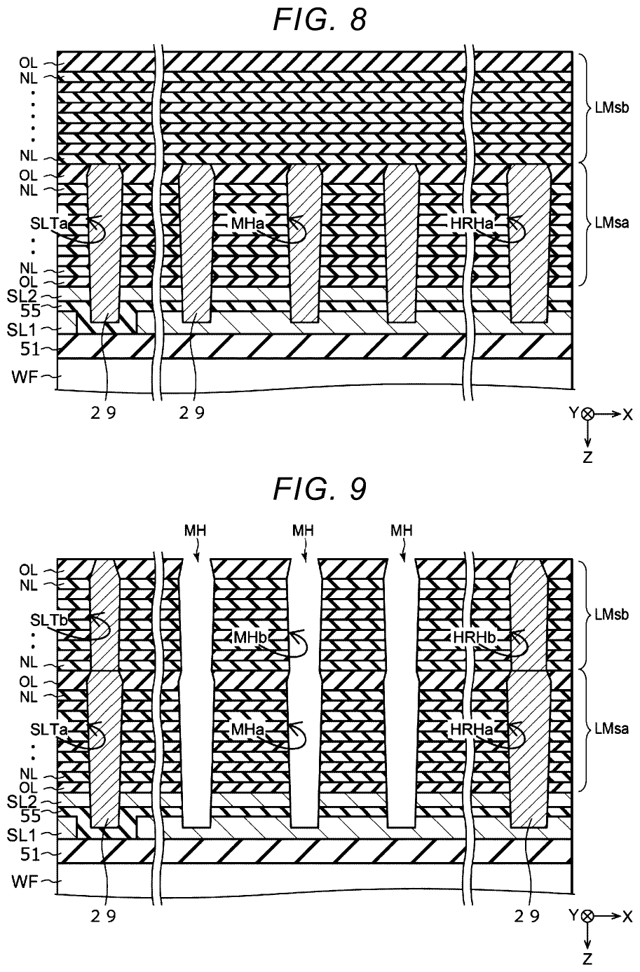

Next, as shown in FIG. 8, a sacrificial layer 29 is filled in the memory holes MHa, the slit portion SLTa, and the hole HRHa. For the sacrificial layer 29, for example, a material having etching selectivity with respect to a material containing silicon such as a silicon oxide, a silicon nitride, or a polysilicon, such as carbon, is used.

A stacked body LMsb is formed above the stacked body LMsa by alternately stacking a plurality of sacrificial layers NL and a plurality of insulating layers OL. The sacrificial layer NL of the stacked body LMsb is replaced with a conductive material in a later replacement step and thus are in the ultimate positions of the word lines WL and the select gate lines SGD.

Next, although not specifically depicted, the sacrificial layers NL and the insulating layers OL are processed into stepped shapes in the staircase region SR of the stacked body LMsb. Next, this staircase region SR is covered with insulating layer 50.

Next, as shown in FIG. 9, a plurality of memory holes MHb extending in the Z direction are formed in the stacked body LMsb. The plurality of memory holes MHb correspond in position to the plurality of memory holes MHa and are thus formed to align with the corresponding memory holes MHa. As a result, each of the memory holes MHb is in communication with a corresponding memory hole MHa. Therefore, the memory holes MHa and MHb corresponding to each other form a single memory hole MH that penetrates the stacked bodies LMsa and LMsb to reach the conductive material SL1.

Next, the sacrificial layer 29 in the plurality of memory holes MHa is removed via the plurality of memory holes MHb. As a result, a plurality of memory holes MH shown in FIG. 9 are formed.

In addition, the slit portion SLTb and the hole HRHb extending in the Z direction can be formed in the stacked body LMsb at the same time as the formation of the memory hole MHb or in a different step. The plurality of slit portions SLTb correspond in position to the plurality of slit portions SLTa, and are thus formed to align with the corresponding slit portions SLTa. Each of the slit portions SLTb communicates with a corresponding slit portion SLTa. Therefore, the slit portions SLTa and SLTb corresponding to each other from one slit SLT that penetrate the stacked bodies LMa and LMb to reach the insulating material 55.

Similarly, the plurality of holes HRHb correspond in position to the plurality of holes HRHa, and are thus formed to align with the corresponding holes HRHa. Each of the holes HRHb communicates with a corresponding hole HRHa. Therefore, the holes HRHa and HRHb corresponding to each other from one hole HRH that penetrate the stacked bodies LMa and LMb to reach the conductive material SL1.

The sacrificial layer 29 can be formed in, or left in, the slits SLT and the holes HRH by using a lithography technology or the like. As a result, the structure shown in FIG. 9 is obtained.

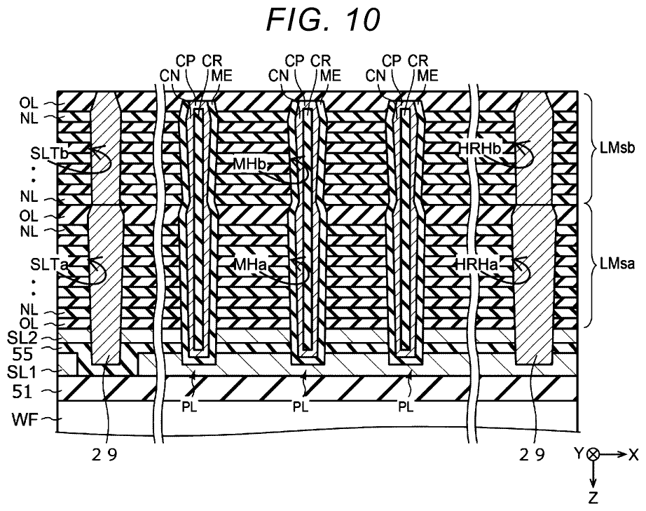

Next, as shown in FIG. 10, the block insulating layer BK, the charge storage layer CT, and the tunnel insulating layer TN (see FIGS. 4 and 5) are stacked in this order on the side wall and the bottom surface of the memory hole MH, and the memory layer ME is formed.

Next, the channel layer CN and the core layer CR are formed in this order in the memory hole MH on the memory layer ME. As a result, the channel layer CN is formed on the memory layer ME of the side surface and the bottom surface of the memory hole MH, and the core layer CR is filled in the center portion of the memory hole MH.

Next, the core layer CR is recessed to a predetermined depth in the memory hole MH, and the cap layer CP is formed on the upper end portion of the memory hole MH. The cap layer CP is electrically connected to the channel layer CN. As a result, the plurality of pillars PL are formed.

Next, the sacrificial layer 29 in the hole HRH is removed. At this time, the holes HRHa and HRHb are in communication with each other. Therefore, the hole HRH penetrates the stacked bodies LMsa and LMsb in the Z direction and reaches the conductive material SL1. Next, the material layers 54 and 24 are formed in the hole HRH. As a result, the support column HR is formed.

Next, the sacrificial layer 29 in the slit SLT is removed. At this time, the slit portions SLTa and SLTb are in communication with each other. Therefore, the slit SLT penetrates the stacked bodies LMsa and LMsb in the Z direction to reach the insulating material 55 and extends lengthwise in the Y direction. In addition, the sacrificial layer NL is exposed on the side wall of the slit SLT.

Next, the sacrificial layers NL of the stacked bodies LMsa and LMsb are removed via the slit SLT. As a result, a space is formed between the insulating layers OL adjacent to each other in the Z direction. At this time, in the staircase region SR in which the pillars PL are not provided, the support columns HR serve to support the insulating layers OL of the stacked bodies LMsa and LMsb, and the bending of the stacked bodies LMsa and LMsb is reduced or avoided.

Next, a conductive material for the word lines WL and the select gate lines SGS and SGD is embedded in the space between the insulating layers OL through the slit SLT. As a result, each sacrificial layer NL is replaced by a word line WL, a select gate line SGS, or a select gate line SGD. That is, the replacement step has been fully executed.

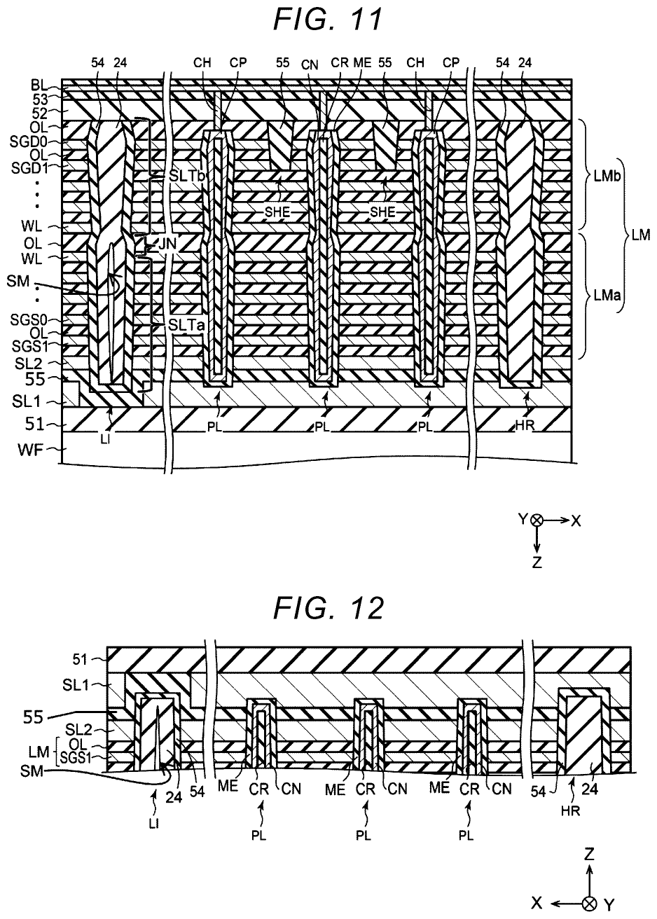

Next, as shown in FIG. 11, the material layer 54 is formed on the inner wall of the slit SLT, and the material layer 24 is embedded in the material layer 54. At this time, the aspect ratio of the slit SLT is not only large, but also the width (in the X direction) is narrowed and constricted at the connection portion JN between the slit portions SLTa and SLTb. Therefore, it is difficult for the material forming the material layer 24 to fill the slit portion SLTa, and a seam SM is likely to remain in the material layer 24 thus formed.

Next, the insulating layers 52 and 53, the plug CH, the bit line BL, and the like are formed on the stacked body LM. As a result, the structure shown in FIG. 11 is obtained. Thereafter, an insulating layer for bonding and a wire or a pad can be formed. As such, an array wafer including a memory cell array is completed.

A peripheral circuit wafer including a peripheral circuit may be formed separately from an array wafer.

The peripheral circuit wafer and the array wafer can then be bonded to one another. The array wafer is bonded to the peripheral circuit wafer with the upper side (−Z side) in FIG. 11 being the bonding surface.

Next, as shown in FIG. 12, the substrate WF of the array wafer is removed. FIGS. 12 to 16 show only a portion of the stacked body LM on the +Z side. Note that FIGS. 12 to 16 are shown in the reversed Z direction from that adopted for FIGS. 6 to 11. Therefore, in FIGS. 12 to 16, the +Z direction is an upward direction.

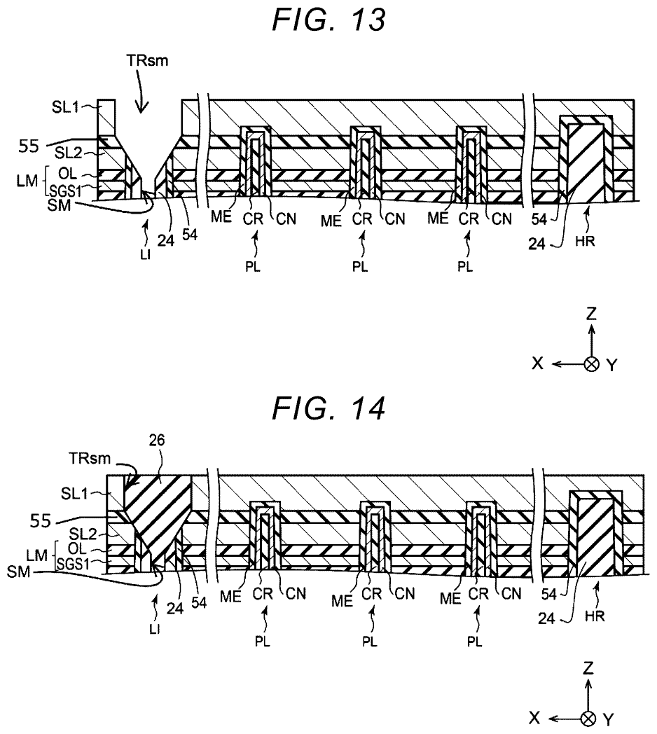

Next, as shown in FIG. 13, the insulating material 51 (for example, a silicon oxide film) is etched. At this time, the conductive material SL1 (for example, polysilicon) functions as an etching stopper, and the pillar PL and the support column HR are not etched. On the other hand, in the region of the plate-shaped body LI from which the conductive material SL1 is removed, the insulating material 55 (for example, a silicon oxide film) is etched together with the etching of the insulating material 51. Then, the material layers 24 and 54 (for example, silicon oxide films) are also etched, and a trench TRsm that reaches the seam SM is formed. The trench TRsm extends in the Y direction along the plate-shaped body LI in the X-Y surface. In this way, the etching of the insulating material 51, the insulating material 55 in the formation region Rslt of the slit, and the material layers 24 and 54 can be performed in the same etching step.

Next, the material layer 26 is deposited in the trench TRsm and the seam SM, and on the conductive material SL1. The material layer 26 is flattened by using a chemical mechanical polishing (CMP) method or the like until the conductive material SL1 is exposed. As a result, as shown in FIG. 14, the material layer 26 is embedded in the trench TRsm and the seam SM. The crack reduction effect can be obtained although there is a portion in which the seam SM remains to some extent inside the material layers 24 and 26.

Next, the conductive material SL1 is etched. At this time, the insulating material 55 functions as an etching stopper. As a result, the memory layer ME at the tip portion of the pillar PL on the +Z side is exposed.

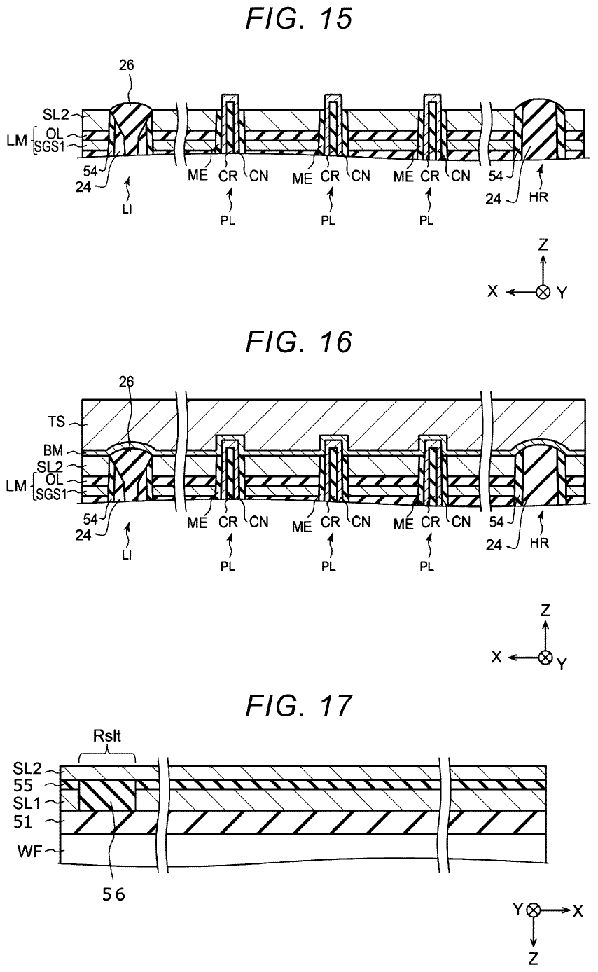

Next, the memory layer ME at the tip portion of the pillar PL on the +Z side is etched together with the insulating material 55. As a result, as shown in FIG. 15, the channel layer CN at the tip portion of the pillar PL on the +Z side is exposed. At this time, a portion of the material layer 26 at the end of the plate-shaped body LI on the +Z side and portions of the material layers 54 and 24 at the end of the support column HR on the +Z side are etched. Therefore, as shown in FIG. 15, by etching the insulating material 55, the material layer 26 may protrude from the surface of the conductive layer SL2 and be left. Alternatively, the material layer 26 may be recessed from the surface of the conductive layer SL2 or may be flush with the surface of the conductive layer SL2. Similarly, the upper end of the support column HR may also protrude from or be recessed from the surface of the conductive layer SL2, or may be flush with the surface of the conductive layer SL2.

Next, as shown in FIG. 16, the barrier metal layer BM and the metal layer TS are deposited on the conductive layer SL2, the channel layer CN, the material layer 26 of the plate-shaped body LI, and the material layers 24 and 54 of the support column HR. As a result, the channel layer CN of the conductive layer SL2 and the pillar PL are connected. The conductive layer SL2 is connected to the barrier metal layer BM and the metal layer TS, and functions as the source layer SL. Therefore, the channel layer CN of the pillar PL is electrically connected to the source layer SL.

Thereafter, the necessary interlayer insulating film 60, the contact, the wiring, and the like are formed, and the semiconductor memory device 1 according to the present embodiment is completed.

According to the first embodiment, although the seam SM may be formed in the material layer 24 of the slit SLT due to the large aspect ratio of the slit SLT and/or the presence of a constriction at the connection portion JN between the slit portions SLTa and SLTb, the material layer 26 embeds the seam SM. As a result, the stacked body LM can be prevented from cracking along the slit SLT.

Further, according to the present embodiment, the insulating material 51, the insulating material 55, and the material layers 24 and 54 at one end of the slit portion SLTa on the +Z side are removed in the same etching step. As a result, the trench TRsm can be connected to the seam SM without an additional step.

In the present embodiment, the plurality of slit portions SLTa and SLTb are formed in stacked bodies LMa and LMb, respectively, corresponding to the plurality of memory holes MHa and MHb or the plurality of holes HRHa and HRHb. However, the slit SLT may be formed in the stacked bodies LMa and LMb at the same time in the same process or the slit SLT may be divided into three or more portions formed at different times or the like.

### Second Embodiment

FIGS. 17 to 19 are cross-sectional views showing an example of a manufacturing method of the semiconductor memory device according to the second embodiment. In general, the structural configuration of the second embodiment may be the same as the configuration of the first embodiment unless otherwise noted.

In the second embodiment, an insulating material 56 is formed in the formation region Rslt for the slit SLT in the process step that was described with reference to FIG. 6. The insulating material 56 is formed at the position of the insulating material 55 and the conductive material SL1 in the formation region Rslt. As a result, the structure shown in FIG. 17 is obtained.

That is, the insulating material 55 and the conductive material SL1 in the formation region Rslt are selectively removed and, after a groove is formed in the formation region Rslt, the insulating material 56 is deposited on the conductive material SL1 and the insulating material 51. Next, the insulating material 56 is polished by using a CMP method or the like until the upper surface of the insulating material 55 is exposed. As a result, the insulating material 56 is embedded in the groove of the formation region Rslt for the slit SLT.

The insulating material 56 is, for example, an insulating material having etching selectivity with respect to a material containing silicon such as a silicon oxide film, a silicon nitride film, or polysilicon. For the insulating material 56, for example, aluminum oxide is used. The insulating material 56 functions as an etching stopper in a formation step of the slit SLT.

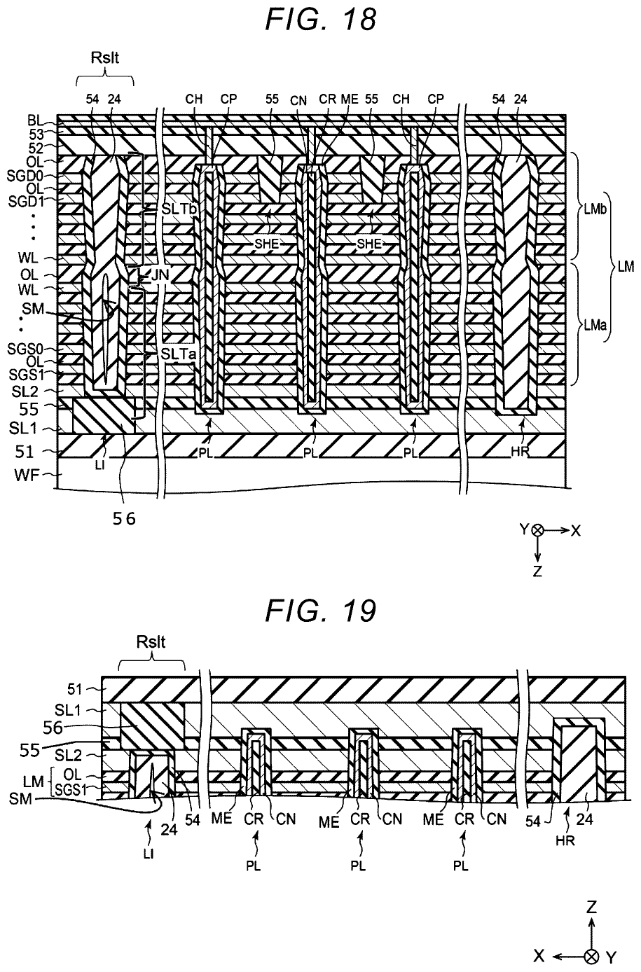

Next, the structure shown in FIG. 18 is obtained by undergoing through the steps as described with reference to FIGS. 7 to 11. In the formation step of the slit SLT, since the insulating material 56 functions as an etching stopper, the slit SLT and the plate-shaped body LI penetrate the stacked bodies LMb and LMa and are formed up to the insulating material 56.

Next, as shown in FIG. 19, the substrate WF of the array wafer is removed. FIG. 19 shows only a portion of the stacked body LM on the +Z side. FIG. 19 is shown in the reversed Z direction with respect to FIGS. 17 and 18. Therefore, in FIG. 19, the +Z direction is described as an upward direction.

Next, as shown in FIG. 13, the insulating material 51 (for example, a silicon oxide film) is etched. At this time, the conductive material SL1 (for example, polysilicon) and the insulating material 56 (for example, aluminum oxide) function as an etching stopper.

Next, the insulating material 56 is selectively etched. As a result, the material layer 54 (for example, a silicon oxide film) is exposed in the formation region Rslt for the plate-shaped body LI.

Next, the material layers 24 and 54 are selectively etched from the −Z side. As a result, the trench TRsm is formed that reaches the seam SM as shown in FIG. 13. The trench TRsm extends in the Y direction along the plate-shaped body LI.

Thereafter, the semiconductor memory device 1 according to the second embodiment is completed through the steps as described with reference to FIGS. 14 to 16. In this way, even in the manufacturing method of the second embodiment, the semiconductor memory device 1 according to the second embodiment can be formed. The configuration of the semiconductor memory device 1 of the second embodiment is similar to the first embodiment. Therefore, the second embodiment can obtain a similar effect as the first embodiment.

### Third Embodiment

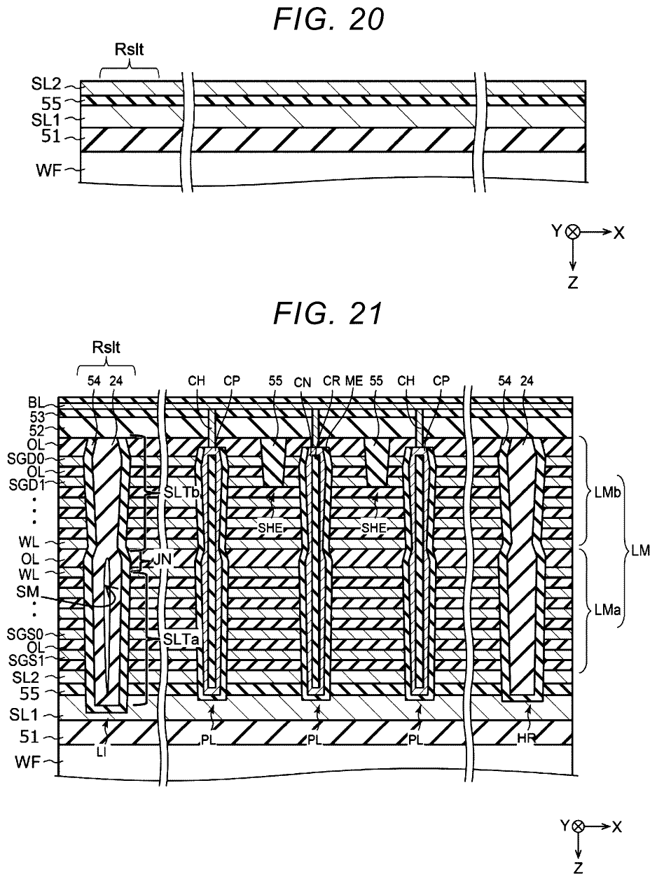

FIGS. 20 to 23 are cross-sectional views showing an example of a manufacturing method of the semiconductor memory device according to the third embodiment. The configuration of the third embodiment is the same as the configuration of the first embodiment unless otherwise noted.

In the third embodiment, in the step described with reference to FIG. 6, in the formation region Rslt for the slit SLT, the conductive material SL1, the insulating material 55, and the conductive layer SL2 are formed on the insulating material 51, in the same manner as in the formation region of the other stacked bodies LM. In the formation region Rslt, the conductive material SL1 is not removed. The insulating material 56 is not present. As a result, the structure shown in FIG. 20 is obtained.

Next, the structure shown in FIG. 21 is obtained by undergoing through the steps as described with reference to FIGS. 7 to 11. The slit SLT and the plate-shaped body LI penetrate the stacked bodies LMb and LMa and reach the conductive material SL1.

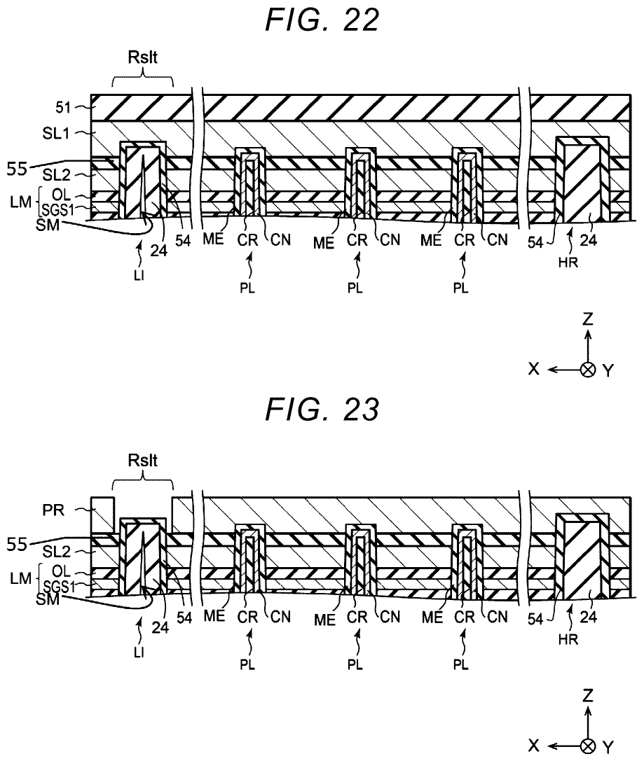

Next, as shown in FIG. 22, the substrate WF of the array wafer is removed. FIGS. 22 and 23 show only a portion of the stacked body LM on the +Z side. FIGS. 22 and 23 are shown in the reversed Z direction with respect to the FIGS. 20 and 21. Therefore, in FIGS. 22 and 23, the +Z direction is described as an upward direction.

Next, as shown in FIG. 23, the insulating material 51 (for example, a silicon oxide film) and the conductive material SL1 (for example, polysilicon) are etched. At this time, the insulating material 55 and the material layer 54 function as an etching stopper.

Next, the insulating layer 56 is selectively etched, which includes selectively etching the material layer from the +Z side using a lithography technology and an etching technology. As a result, the material layer 54 (for example, a silicon oxide film) is exposed in the formation region Rslt for the plate-shaped body LI.

Next, the material layers 24 and 54 are selectively etched from one end of the slit SLT on the −Z side. As a result, the trench TRsm is formed that reaches the seam SM as shown in FIG. 13. The trench TRsm extends in the Y direction along the plate-shaped body LI.

Thereafter, the semiconductor memory device 1 according to the third embodiment is completed through the steps as described with reference to FIGS. 14 to 16. As described above, even in the manufacturing method of the third embodiment, the semiconductor memory device 1 according to the present embodiment can be formed. The configuration of the semiconductor memory device 1 of the third embodiment may similar to the first embodiment. Therefore, the third embodiment can obtain as similar effect as the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device, comprising:
a first stacked body in which first conductive layers and first insulating layers are alternately stacked in a first direction;
a second conductive layer on a first side of the first stacked body in the first direction;
a pillar extending in the first direction in the first stacked body, the pillar including a semiconductor layer;
a slit in the first stacked body extending in the first direction and in a second direction intersecting the first direction, the slit having a width dimension in a third direction intersecting the first and second directions;
a first material layer on sidewalls of the slit on a first end side of the slit in the first direction; and
a second material layer in the slit between the first material layer on the sidewalls in the third direction, wherein
the second material layer has sidewalls on the first end side of the slit which taper outwardly from a center of the slit, and
the first material layer has sidewalls on the first end side of the slit which correspondingly taper outwardly from the center of the slit with the sidewalls of the second material layer.

2. The semiconductor memory device according to claim 1, wherein the second material layer increases in width in the second direction as it approaches the second conductive layer.

3. The semiconductor memory device according to claim 2, wherein the thickness of the first material layer on the sidewalls of the slit decreases in the second direction as the second conductive layer approaches.

4. The semiconductor memory device according to claim 1, wherein the thickness of the first material layer on the sidewalls of the slit decreases in the second direction as the second conductive layer approaches.

5. The semiconductor memory device according to claim 1, wherein the second material layer extends from the slit in the first direction beyond the first stacked body.

6. The semiconductor memory device according to claim 1, wherein the second material layer fills a seam in the first material layer between the sidewalls of the slit.

7. The semiconductor memory device according to claim 1, further comprising:
a second stacked body in which third conductive layers and third insulating layers are alternately stacked in the first direction, the second stacked body being on the first stacked body, wherein
the semiconductor layer of the pillar extends in the first direction through the first and second stacked bodies,
the slit extends in the first direction through the first and second stacked bodies in the first direction and in the second direction, and
the width dimension of the slit narrows in the third direction in a junction region of the first and second stacked bodies.

8. The semiconductor memory device according to claim 7, wherein a width dimension of the first material layer in the third direction is reduced in the junction region.

9. The semiconductor memory device according to claim 7, wherein the width dimension of the slit in the second stacked body changes outside the junction region.

10. The semiconductor memory device according to claim 1, wherein the first material layer is an electrical insulator.

11. The semiconductor memory device according to claim 1, wherein the first material layer comprises:
a sidewall layer contacting the sidewalls of the slit, and
an inner layer between the sidewall layer in the third direction.

12. The semiconductor memory device according to claim 11, wherein
the sidewall layer is an electrical insulator material, and
the inner layer is an electrical conductor material.

13. The semiconductor memory device according to claim 11, wherein the sidewall layer and the inner layer are each an electrical insulator material.

14. The semiconductor memory device according to claim 11, wherein the sidewall layer is a silicon oxide film.

15. A semiconductor memory device, comprising:
a stacked body in which first conductive layers and first insulating layers are alternately stacked in a first direction;
a second conductive layer on a first side of the first stacked body in the first direction;
a plurality of memory pillars extending in the first direction in the stacked body;
a plurality of slits dividing the stacked body into a plurality of memory blocks, each slit extending in the first direction and in a second direction intersecting the first direction in the stacked body and having a width dimension in a third direction intersecting the first and second directions;
a first material layer on sidewalls of each slit on a first end side of the slit in the first direction; and
a second material layer in each slit between the first material layer on the sidewalls of the slit in the third direction, wherein
the second material layer has sidewalls on the first end side of the slit which taper outwardly from a center of the slit, and
the first material layer has sidewalls on the first end side of the slit which correspondingly taper outwardly from the center of the slit with the sidewalls of the second material layer.

16. The semiconductor memory device according to claim 15, wherein the first material layer comprises:
a sidewall layer contacting the sidewalls of the slit, and
an inner layer between the sidewall layer in the third direction.

17. The semiconductor memory device according to claim 16, wherein
the sidewall layer is an electrical insulator material, and
the inner layer is an electrical conductor material.

18. The semiconductor memory device according to claim 15, wherein the thickness of the first material layer on the sidewalls of the slit decreases in the second direction as the second conductive layer approaches.

19. The semiconductor memory device according to claim 15, wherein the second material layer extends from the slit in the first direction beyond the first stacked body.

20. A manufacturing method of a semiconductor memory device comprising:
forming a first stacked body by alternately stacking a plurality of sacrificial layers and a plurality of first insulating layers one by one in a first direction above a second conductive layer;
forming a pillar including a semiconductor layer that extends in the first direction in the first stacked body;
forming a slit that penetrates the first stacked body in the first direction and extends in a second direction intersecting the first direction;
forming a void space between the plurality of first insulating layers by removing the plurality of sacrificial layers via the slit;
depositing a material for a plurality of first conductive layers in the void space between the plurality of first insulating layers via the slit;
forming a first material layer in the slit;
etching the first material layer from one end of the slit on a second conductive layer side; and
forming a second material layer in the slit from the one end of the slit to fill a seam in the first material layer.
